(19) United States
(12) Patent Application Publication
(10) Pub. No.: US 2026/0246466 A1
(43) Pub. Date: Aug. 20, 2026

(54) ASYMMETRIC DRIVERS AND METHODS OF DRIVING LOGIC CELL NETWORKS USING THE SAME

(71) Applicant: Micron Technology, Inc., Boise, ID (US)

(72) Inventor: Leon Zlotnik, Camino, CA (US)

(21) Appl. No.: 19/529,724

(22) Filed: Feb. 4, 2026

Related U.S. Application Data
(60) Provisional application No. 63/759,329, filed on Feb. 17, 2025.

(51) Int. Cl. H03K 19/0944; H03K 3/037

(52) U.S. Cl. CPC H03K 19/0944; H03K 3/037

(57) ABSTRACT

The present application relates to asymmetric drivers and methods of driving logic cell networks using the same. For example, a first logic cell network can comprise a first plurality of logic cells associated with a non-static signal path, and a second logic cell network can comprise a second plurality of logic cells associated with a quasi-static signal path. The second plurality of logic cells includes a plurality of drivers configured to have an asymmetric drive strength.

### PRIORITY INFORMATION

This Application claims the benefits of U.S. Provisional Application No. 63/759,329, filed on Feb. 17, 2025, the contents of which are incorporated herein by reference.

### TECHNICAL FIELD

Embodiments of the disclosure relate generally to electronic devices, and more specifically, relate to asymmetric drivers and methods of driving logic cell networks using the same.

### BACKGROUND

Various types of electronic devices include digital logic circuits and memory systems that may store and process data. A digital logic circuit is an electronic circuit that processes digital signals or binary information, which can take on two possible values (usually represented as 0 and 1). The digital logic circuit can use logic gates to manipulate and transform the digital signals or binary information. Digital logic circuits can be, for example, used in a wide range of electronic devices including computers, calculators, digital clocks, and many other electronic devices that employ digital processing. Digital logic circuits can be designed to perform specific logical operations on digital inputs to generate digital outputs, and, in some instances, can be combined to form more complex circuits to perform more complex operations. A memory device can include one or more memory devices that store data. The memory devices can be, for example, non-volatile memory devices and volatile memory devices. In general, a host system can utilize a memory system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1 illustrates an example electronic system that includes an asymmetric driver used to drive a quasi-static signal associated with a logic cell network in accordance with various embodiments of the present disclosure.

FIG. 2 illustrates a number of logic cell networks in which a number of asymmetric drivers in accordance with various embodiments of the present disclosure can be implemented.

FIG. 3A illustrates a driver configured to have an asymmetric drive strength for driving a quasi-static logic cell network in accordance with various embodiments of the present disclosure.

FIG. 3B illustrates a driver configured to have an asymmetric drive strength for driving a quasi-static logic cell network in accordance with various embodiments of the present disclosure.

FIG. 4A illustrates an example of a transistor used to form an asymmetric driver in accordance with various embodiments of the present disclosure.

FIG. 4B illustrates an example of a transistor used to form an asymmetric driver in accordance with various embodiments of the present disclosure.

FIG. 5 illustrates an example of a signal that can be driven by an asymmetric driver within a logic cell network in accordance with various embodiments of the present disclosure.

### DETAILED DESCRIPTION

Aspects of the present disclosure are directed to asymmetric driving of logic cell networks having signal paths that can be static, non-static, and/or quasi-static.

Logic cell networks (e.g., “nets”) can comprise numerous logic cells including various types of logic gates, flip-flops, latches, buffers, inverters, repeaters, adders, multiplexors, etc. Such logic cells are generally built to have the same driving strength for signal transitions from 1 to 0 and from 0 to 1. In various current and/or prior approaches, multiple cells (e.g., buffers, inverters, signal shapers, etc.) are added to signal paths to ensure proper transition timing and drive strength. However, for quasi-static networks (e.g., networks corresponding to quasi-static paths), adding such cells can be an unnecessary over-constraint since such paths have different driving strength and reduced transition time requirements. For example, meeting transition time specifications for switching single clock paths is less crucial (e.g., not necessary) for quasi-static nets (e.g., they can have different transition timing requirements for 1 to 0 and 0 to 1 transitions). Also, utilizing symmetric drivers to provide equivalent driving strength for 1 to 0 and 0 to 1 transitions can lead to increased current leakage for quasi-static paths depending on whether the quasi-static state to be driven is a 1 or 0.

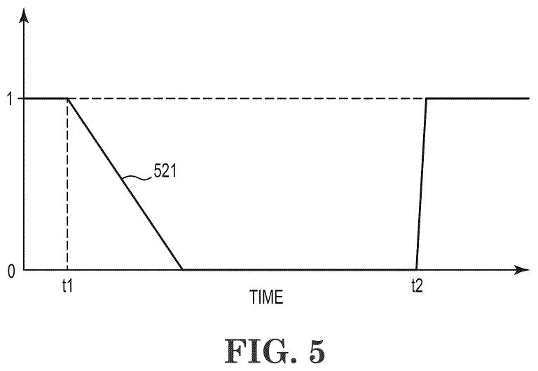

Various embodiments of the present disclosure address the above deficiencies by providing asymmetric drivers for particular logic cell networks (e.g., quasi-static nets). For example, in an electronic system comprising both quasi-static paths and non-static (e.g., switching) paths, embodiments of the present disclosure can provide asymmetric drivers for the quasi-static path(s). As used herein, a quasi-static path refers to a signal path associated with a signal having asymmetric and/or asynchronous characteristics. For example, a quasi-static signal can include a signal that generally remains static during a particular functional mode. Such signals can be associated with asymmetric transition timing requirements. For instance, a quasi-static signal can be asynchronous (relative to a clock signal) for either 1 to 0 or 0 to 1 transitions, or both. For example, a quasi-static signal can be a signal having asynchronous timing requirements for a 1 to 0 transition and a synchronous timing requirement for a 0 to 1 transition. In such an example, it can be beneficial to drive the quasi-static signal via an asymmetric “strong 1” driver (and “weak 0 driver) to meet synchronous 0 to 1 transition timing parameters. Examples of quasi-static signals/paths can include, but are not limited to, Design For Test (DFT) related signals such as scan enable (SE), power management signals (e.g., deep sleep (DS), shut down, wake), and reset (RST) signals. One example of a quasi-static signal is described below in association with FIG. 5.

Providing asymmetric driving of quasi-static paths can provide various benefits such as providing power savings (e.g., via reduced leakage) and/or area savings as compared to providing equivalent drive strength for such quasi-static paths. As an example, an asymmetric driver for driving a quasi-static “0” can be configured for reduced leakage while driving a “0” state, and an asymmetric driver for driving a quasi-static “1” can be configured for reduced leakage while driving a “1” state (as compared to symmetric driver configured for equivalent driving strength). As described further below, the asymmetric drive strength for the asymmetric drivers can be accomplished in various manners. For example, the physical characteristics of the constituent transistors (e.g., NMOS and/or PMOS) can be configured (e.g., tuned) to provide different particular impedances (e.g., resistances) or impedance ratios to provide the desired driving characteristic (e.g., “strong” driver for 1 and “weak” driver for 0 or vice versa).

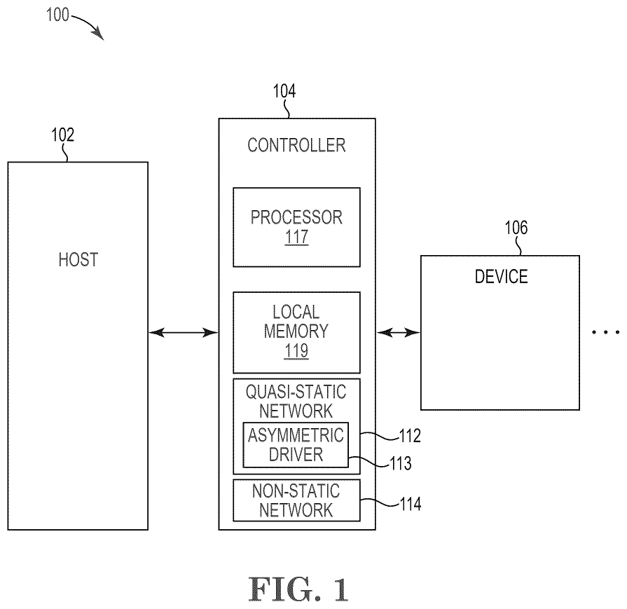

FIG. 1 illustrates an example electronic system 100 that includes an asymmetric driver 113 used to drive a quasi-static signal associated with a logic cell network in accordance with various embodiments of the present disclosure. In this example, the system 100 includes a host 102, a controller 104, and a device 106; although, embodiments are not so limited.

The electronic system 100 can be, or can be part of, for example, a desktop computer, laptop computer, televisions, home theater system, gaming console, digital camera, network router and/or switch, printer, scanner, medical device, GPS navigation device, home device (e.g., thermostat, doorbell camera, security camera, smart lock, etc.), wearable device, industrial control system (e.g., automated industrial and/or control device) mobile computing device, a vehicle (e.g., airplane, drone, train, automobile, or other conveyance), Internet of Things (IoT) enabled device, embedded computer (e.g., one included in a vehicle, industrial equipment, or a networked commercial device), system-on-chip (SoC), chipset (e.g., a collection of integrated circuits), tile, Field-Programmable Gate Array (FPGA) structure (e.g., segmented FPGA structure), or other such device.

The electronic system 100 can be, or can include, a computing fabric. As used herein, the term “computing fabric” generally refers to a conveying, multiplexing, network, computing, or communication topology in which components pass data to each other through interconnecting switches, hubs, routers, multiplexers, buses, transmission lines and rings, cables, optical couplers and fibers, electromagnetic devices, or various other means. For example, a “computing fabric” can include various components (e.g., interconnects, crossbars, networks on chip, token rings, etc.) within a computing, memory, data storage and/or processing, network and/or telecommunication, artificial intelligence, control and/or telemetry, digital entertainment and/or other system, that facilitates in-chip and/or inter-chip communication.

The electronic system 100 includes a host 102. The host 102 can include a processor chipset and a software stack executed by the processor chipset. For example, the host 102 can be, or can include, a central processing unit (CPU) or a CPU complex that can be configured to execute an operating system.

The host 102 can be coupled to the controller 104 via a physical and/or logical host interface that operates based on various communication protocols and to provide control, address, data, and other signals to the controller 104 (e.g., to further cause the controller 104 to control the device 106). Examples of the interface between the host 102 and the controller 104 can include, but not limited to, a bus interface (e.g., a serial advanced technology attachment (SATA) interface, a Serial Attached SCSI (SAS) interface, a Serial Attached SCSI (SAS) interface, a Small Computer System Interface (SCSI), a peripheral component interconnect express (PCIe) interface, ISA, etc.), a memory interface (e.g., a double data rate (DDR) interface, a dual in-line memory module (DIMM) interface, an Open NAND Flash Interface (ONFI) interface, an NVM Express (NVMe) interface), a Fibre Channel, an UART interface, an I2C interface, a Serial Peripheral Interface (SPI), an Universal Serial Bus (USB) interface, an ethernet interface, a general-purpose input/output (GIPO) interface, a custom interface, etc.

The controller 104 is communicatively coupled to one or more electronic devices 106 such that signaling can be exchanged therebetween. Non-limiting examples of the devices 106 can include microcontrollers, microprocessors, digital logic circuits, analog circuits, light emitting diodes (LEDs), displays, sensors, motors, actuators, audio amplifiers, radio frequency (RF) circuits, test and measurement instruments (e.g., oscilloscopes, multimeters, etc.), automotive electronics, medical devices, telecommunication equipment, memory devices (e.g., volatile and/or non-volatile memory devices), graphics processing units, processors/co-processors, logic blocks, intellectual property (IP) cores, etc. As used herein, a “core” or “IP core” generally refers to one or more blocks of data and/or logic that form constituent components of an application-specific integrated circuit or field-programmable gate array. The circuit portion areas can be designed, built, and/or otherwise configured to perform specific tasks and/or functions within the systems described herein.

As shown in FIG. 1, the controller 104 can include a processing device (e.g., processor 117) that can execute instructions stored in a local memory 119 to perform various operations described herein. The controller 104 can include various special purpose circuitry in the form of an ASIC, FPGA, state machine, and/or other logic circuitry that can perform operations described herein. As an example, the controller 104 can be a memory controller.

In various embodiments, one or more constituent components (e.g., host 102, controller 104, device 106, etc.) of system 100 can be part of a SoC. In one example, a device 106 itself can correspond to an SoC, while the host 102 and the controller 104 are considered “external” to the SoC. In another example, the host 102 or the controller 104, or both, can be considered as a part of an SoC along with the device 106 being internal or external to the SoC.

The controller 104 can include a number of logic cell networks, which can be referred to as “nets.” In the example shown in FIG. 1, the controller 104 includes a quasi-static logic cell network 112 and a non-static logic cell network 114. The logic cell networks comprise multiple logic cells (e.g., components) that receive and propagate signals corresponding to logic values. Examples of logic cells include, but are not limited to buffers, flip flops, logic gates (e.g., NAND, NOR, etc.), inverters, latches, memory cells, isolation cells, and level shifters. An example of a non-static logic cell network or a non-static signal path is a data input/output (I/O) signal which often provides multiple state transitions over a number of clock cycles. Examples of quasi-static signal paths include those corresponding to DFT signals (e.g., scan enable), power management signals (e.g., deep sleep), and reset signals.

In various embodiments, and as shown in FIG. 1, the quasi-static network 112 includes a number of asymmetric drivers 113. As described further below, the asymmetric driver 113 can be, for example, a buffer driver configured to asymmetrically drive signals (e.g., quasi-static signals) by serving as a “strong” driver for a logic “1” and a “weak” driver for a logic “0” or vice versa. Providing asymmetric drivers 113 in a quasi-static net can prevent over-constraining of the signal path since a quasi-static signal generally has reduced transition time requirements and a reduced need for equivalent drive strength as compared to non-static nets, for example. Although the quasi-static network 112 and corresponding asymmetric driver 113 thereof are shown as being on controller 104, embodiments are not so limited. For instance, a quasi-static logic cell network 112 can be additionally or alternatively located on the host 102 and/or on the device 106.

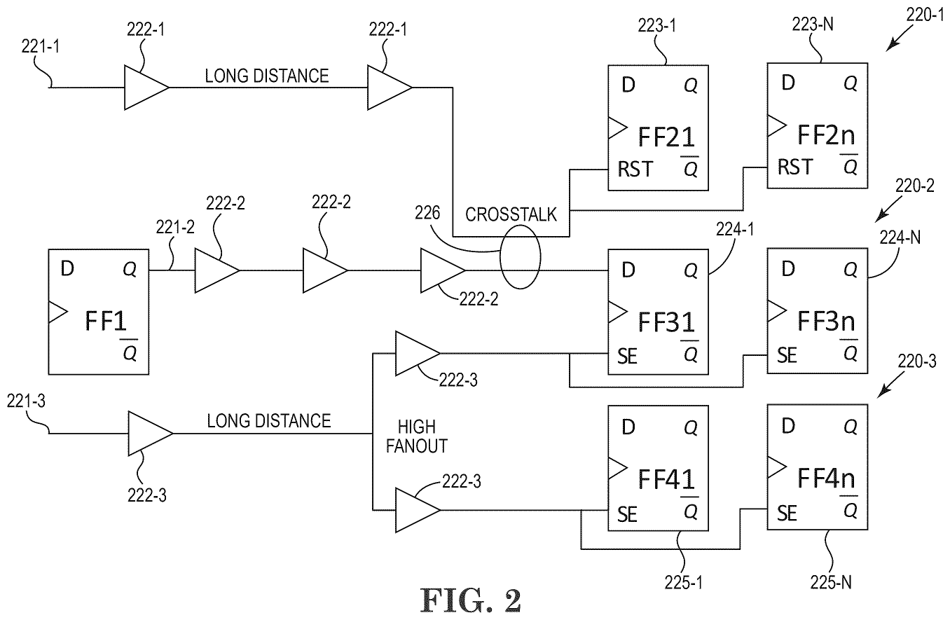

FIG. 2 illustrates a number of logic cell networks 220-1, 220-2, and 220-3 in which a number of asymmetric drivers in accordance with various embodiments of the present disclosure can be implemented. The logic cell networks 220-1, 220-2, and 220-3 can be cell networks such as 112 and 114 shown in FIG. 1. In this example, the logic cells comprise various buffers and flip-flops; however, embodiments are not so limited and can include various other circuit components. In FIG. 2, logic cell network 220-1 represents a signal path associated with signal 221-1, and logic cell networks 220-2 and 220-3 represent signal paths associated with signals 221-2 and 221-3. The various buffers 222-1, 222-2, and 222-3 (referred to collectively as buffers 222) can be used to assist with satisfying transition and delay time specifications that may be applicable (e.g., to ensure proper timing closure). As shown in FIG. 2, the buffers 222 can be used to adjust (e.g., delay and/or strengthen) the corresponding signals due to phenomena such as “cross talk” coupling between signal paths, “high fanout”, and/or “long distance” of wires corresponding to the signal paths.

However, for quasi-static logic cell networks, the addition of such buffers may be unnecessary since the corresponding signal is quasi-static (e.g. not switching between logic states) and the timing requirements can be relaxed for such quasi-static signals. Also, for non-static networks, it can be beneficial for corresponding driver circuits to provide an equivalent driving strength for propagating the signal. However, drivers providing equivalent drive strength can provide increased current leakage when used in quasi-static networks whose corresponding signal path is generally static during operation mode (e.g., “mission mode). As such, it can be beneficial to utilize asymmetric drivers in quasi-static nets to reduce area and provide power savings as compared to if symmetric drivers were used in the quasi-static nets.

In various instances, tools such as place and route (P&R) tools and/or static timing analysis (STA) tools can be used to determine and provide a fixed transition time for logic cell networks regardless of the actual timing behavior, since such tools may be unaware whether the signal path is switching, static, or quasi-static. In such instances, nets having quasi-static signal paths can be identified and asymmetric drivers can be used in such paths in order to provide the benefits of reduced area (e.g., due to eliminating the need to add one or more additional buffers) and/or improved power consumption (e.g., by reducing current leakage depending on which quasi-static state is being driven).

In FIG. 2, the signal path associated with logic cell net 220-1 represents a quasi-static signal path in which signal 221-1 is a reset (RST) signal propagated to logic cells 222-1, 223-1, and 223-N. In this example, the logic cells 223-1 and 223-N are flip flops with the quasi-static reset signal 221-1 being provided to input RST thereof. The RST signal 221-1 is quasi-static since it is configured to go from a logic “1” state to a logic “0” state and remain at that state (e.g., without switching) during a mission mode. In this example, “1” corresponds to the reset state and “0” corresponds to the operation mode. As such, after a short period of reset, most of the logic cells 223 enter the operational mode and stay there (e.g., at state “0”) for an extended time frame. The assertion of reset (e.g., the transition from “0” to “1”) can be relatively slow since most systems are insensitive to the timing of reset assertion (e.g., they are asynchronous). However, many systems may generally require a relatively fast transition out of the reset state (transition from “1” to “0”) in order for the logic cells 223 to get out of reset simultaneously (e.g., synchronously). As described above, a signal can be considered quasi-static if it generally remains static during a particular functional mode and can be associated with asymmetric transition timing requirements.

In FIG. 2, the signal 221-2 associated with logic cell net 220-2 represents a non-static signal 221-2 being propagated to logic cells 222-2, 224-1, and 224-N. For example, unlike a quasi-static signal such as a reset signal that is configured to remain static during a mission mode, the signal 221-2 can be configured to switch states multiple times over a particular time period. For instance, signal 221-2 can correspond to a data signal.

In FIG. 2, the signal 221-3 associated with logic cell net 220-3 and 220-2 represents a quasi-static signal 221-3 being propagated to logic cells 222-3, 224-1, 224-N, 225-1, and 225-N. In this example, the signal 221-3 is a quasi-static scan enable (SE) signal 221-3. For example, as shown in FIG. 2, the signal 221-3 is provided to an SE input of the logic cells (e.g., flip-flops) 224-1, 224-N, 225-1, and 225-N. The SE signal 221-3 can be provided, for example, in association with Design For Test (DFT) operations. As an example, the SE signal 221-3 can remain static while in all non-DFT modes; however, while in DFT mode it can toggle/transition between states with the transitions having relaxed timing specifications (e.g., slower transition times relative to non-DFT modes).

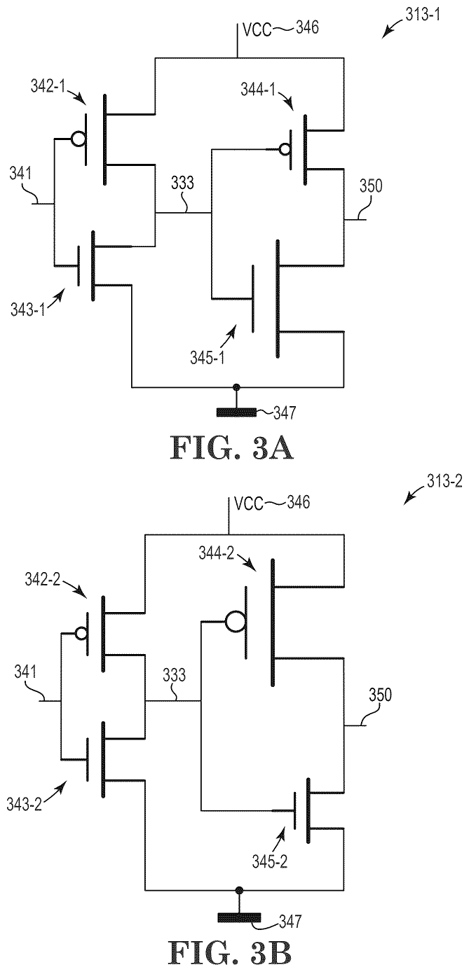

Although not explicitly shown in FIG. 2, the various buffers 222 and/flip flops 223, 224, and 225 can comprise asymmetric drivers in accordance with various embodiments described herein. The asymmetric drivers can be buffer drivers such as those described in FIG. 3A and FIG. 3B, for example. Each logic cell of the nets 220 can include multiple asymmetric drivers therein (e.g., cascaded drivers). The asymmetric drivers can be configured to drive a “strong 1” or a “strong 0” depending on which quasi-static state is to be driven. For example, if the quasi-static state to be driven is a logic “1,” then the asymmetric driver(s) can be constructed so as to provide a relatively fast transition to “1” (as compared to the transition to “0”) and to provide decreased current leakage while in the “1” state (as compared to the current leakage when in the “0” state). As described further below, the asymmetric drivers can comprise CMOS inverters whose constituent PMOS and NMOS transistors comprise different physical characteristics tuned to achieve desired drive strength, leakage, etc. For example, the relative resistance (e.g., on-resistance) between the transistors can be adjusted by providing different channel lengths, channel widths, quantities of gate fingers, etc. In some instances, the on-resistance difference between the PMOS and NMOS transistors of an inverter pair of transistors can be two times, three times, four times, five times, nine times, etc.

FIG. 3A and FIG. 3B illustrate respective drivers 313-1 and 313-2 configured to have an asymmetric drive strength for driving a quasi-static logic cell network in accordance with various embodiments of the present disclosure. The drivers 313-1 and 313-2 can be an asymmetric driver such as driver 113 of FIG. 1, for example.

The asymmetric driver 313-1 is configured to drive a quasi-static state of “0” (e.g., GND voltage 347) and as such is a “strong” driver for “0” and a “weak” driver for “1” (e.g., VCC 346). The asymmetric driver 313-2 is configured to drive a quasi-static state of “1” and as such is a “strong” driver for “1” and a “weak” driver for “0.” In the examples shown in FIG. 3A and FIG. 3B, the drivers are CMOS buffer drivers each comprising a pair of cascaded inverters and can be referred to as “two-stage” buffer drivers.

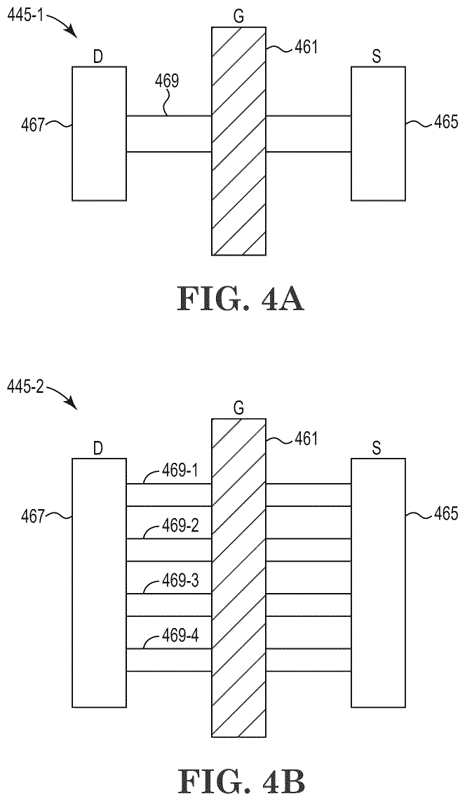

For example, driver 313-1 comprises a first inverter comprising PMOS transistor 342-1 and NMOS transistor 343-1 cascaded with a second inverter comprising PMOS transistor 344-1 and NMOS transistor 345-1. Accordingly, the output 333 of the first inverter is provided as the input to the second inverter. In this example, since the driver 313-1 is configured to drive a strong “0,” the NMOS transistor 345-1 is configured to have a lower impedance as compared to the PMOS transistor 344-1. Such a configuration of driver 313-1 provides a strong quasi-static “0” state (fast transition from “1” to “0”) with reduced leakage as compared to a driver having an equivalent drive strength for states “1” and “0.” The desired difference in on-resistance between the constituent PMOS/NMOS transistors of the inverters can be accomplished in various manners. For example, various physical characteristics and/or topologies can be tuned to achieve a particular impedance difference. For instance, as described further below in association with FIG. 4A and FIG. 4B, a quantity of gate “fingers” and/or channel “fins” of the transistors and/or how they are connected (e.g., serially or in parallel) can be adjusted to alter the on-resistance of a particular transistor. For example, in general, fins can be coupled in parallel to achieve a relatively lower resistance and can be coupled in series to achieve a relatively higher resistance. As another example, a resistance of a FET can be increased by series-connecting multiple FETs. Embodiments are not limited to a particular transistor type or configuration used to accomplish the asymmetric drive strength. For instance, the transistors can be FinFETs or can be planar topologies such as planar MOSFETs. As one example, the channel lengths and/or widths can be adjusted between the PMOS/NMOS transistors (e.g., 344-1/345-1 and/or 342-1/343-1) to affect the on-resistance difference. In general, a wider channel results in a lower resistance. Due to the configuration of buffer 313-1 as a “strong” driver for state “0,” the transition from “1” to “0” at the output 350 (due to transition of the state of input 341 from “1” to “0”) occurs faster than the transition from “0” to “1” at the output 350 (due to transition of the state of input 341 from “0” to “1”).

In the example shown in FIG. 3B, driver 313-2 comprises a first inverter comprising PMOS transistor 342-2 and NMOS transistor 343-2 cascaded with a second inverter comprising PMOS transistor 344-2 and NMOS transistor 345-2. In this example, since the driver 313-2 is configured to drive a strong “1,” the NMOS transistor 345-2 is configured to have a higher resistance as compared to the PMOS transistor 344-2. Such a configuration of driver 313-2 provides a strong quasi-static “1” state (fast transition from “0” to “1”) with reduced leakage as compared to a driver having an equivalent drive strength for states “1” and “0.”

FIG. 4A and FIG. 4B illustrate respective examples of transistors 445-1 and 445-2 used to form an asymmetric driver in accordance with various embodiments of the present disclosure. The example of FIG. 4A is a FET (e.g., a FinFET) having a gate 461, which can be referred to as a “finger,” and a single channel 469, which can be referred to as a “fin,” between a drain region 467 and a source region 465. As described below, the particular physical configuration of the transistor 445-1 (e.g., the quantity of fingers, the quantity of fins, the channel length and/or width, etc.) can depend on the desired on-resistance and current leakage characteristics of transistor 445-1. For instance, the quantity of channels 469 can be increased to reduce the on-resistance of the transistor 445-1 or the quantity of channels 469 can be reduced to increase the on-resistance.

The example of FIG. 4B is a FET 445-2 having multiple parallel channels 469-1, 469-2, 469-3, 469-4 (referred to collectively as channels 469) between drain region 467 and source region 465. In this example, the transistor 445-2 is a FinFET having a single gate/finger 461. Such a configuration results in a decreased on-resistance as compared to the FinFET 445-1. The quantity of fins 469 depends on the desired on-resistance and current leakage characteristics of transistor 445-2. For instance, the quantity of fins 469 can be increased to decrease the on-resistance of the transistor 445-2 or the quantity of gates/fingers 461 can be adjusted to change the on-resistance.

The FETs 445-1 and 445-2 can correspond to respective PMOS and NMOS transistors, or vice versa. As described herein, for example in FIG. 3A and FIG. 3B, the transistors 445-1 and 445-2 can be coupled to form inverters, and inverter pairs can be cascaded to form buffer drivers, for example. The determination of whether transistors 445-1 and 445-2 are PMOS or NMOS, as well as their particular physical characteristics (e.g., the quantity of gate fingers 461, the quantity of channels 469, and/or whether they are connected in parallel or in series, etc.) can be adjusted (e.g., tuned) to achieve asymmetric drivers having particular attributes. For example, characteristics of transistors 445-1 and 445-2 can be selected to provide an asymmetric driver configured to drive a strong quasi-static “0” state or a strong quasi-static “1.”

FIG. 5 illustrates an example of a signal 521 that can be driven by an asymmetric driver within a logic cell network in accordance with various embodiments of the present disclosure. In this example, the asymmetric driver is configured as a “strong 1” driver and a “weak 0” driver. Accordingly, the state transitions (e.g., from 1 to 0 and from 0 to 1) are asymmetric with the transition from 1 to 0 (e.g., at time t1) being much slower than the transition from 0 to 1 (e.g., at time t2). As an example, signal 521 can be a reset signal such as signal 221-1 shown in FIG. 2. In this example, the timing requirements corresponding to assertion of the reset signal at time t1 are relaxed with respect to the timing requirements corresponding to de-assertion of the reset signal at time t2. That is, the entry into the reset state can be an asynchronous event, so a “fast” transition from 1 to 0 is not necessary. For example, it is acceptable for the transition from 1 to 0 to be gradual since the transition is an asynchronous event such that it is acceptable for the transition to take several clock cycles. However, transition out of the reset state (e.g., from 0 to 1) at time t2 can be a synchronous event such that a fast transition is needed (e.g., strong 1) to meet timing requirements (e.g., such that a number of logic cells within the quasi-static network transition out of reset at the same time).

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. An apparatus, comprising:
a first logic cell network comprising a first plurality of logic cells associated with a non-static signal path; and
a second logic cell network comprising a second plurality of logic cells associated with a quasi-static signal path, wherein the second plurality of logic cells includes a plurality of drivers configured to have an asymmetric drive strength.

2. The apparatus of claim 1, wherein the quasi-static signal path is associated with a corresponding quasi-static signal to be driven at a particular state during an operating mode, and wherein the asymmetric drive strength is based on the particular state.

3. The apparatus of claim 2, wherein at least one of the plurality of drivers comprises a PMOS transistor and an NMOS transistor, wherein the PMOS transistor is configured to have a higher associated resistance than a resistance of the NMOS transistor.

4. The apparatus of claim 3, wherein the NMOS transistor comprises multiple gate fingers.

5. The apparatus of claim 2, wherein at least one of the plurality of drivers comprises a PMOS transistor and an NMOS transistor, wherein the PMOS transistor is configured to have a lower associated resistance than a resistance of the NMOS transistor.

6. The apparatus of claim 5, wherein the PMOS transistor comprises multiple gate fingers.

7. The apparatus of claim 1, wherein the plurality of drivers comprise at least one buffer driver including a first pair of transistors cascaded with a second pair of transistors.

8. The apparatus of claim 1, wherein the non-static signal path includes a first corresponding signal having state transition timing requirements that are symmetric to each other, and wherein the quasi-static signal path includes a second corresponding signal having state transition timing requirements that are asymmetric to each other such that a transition to one state is faster than a transition to a different state.

9. The apparatus of claim 8, wherein the second corresponding signal is asynchronous for either or both of state transitions from 1 to 0 and from 0 to 1.

10. The apparatus of claim 9, wherein the quasi-static signal path corresponds to a signal selected from a group of signals, comprising:
a scan enable (SE) signal;
a deep sleep (DS) signal; and
a reset (RST) signal.

11. A method, comprising:
providing a first signal to a first logic cell network comprising a first plurality of logic cells associated with a non-static signal path; and
providing a second signal to a second logic cell network comprising a second plurality of logic cells associated with a quasi-static signal path, wherein the second plurality of logic cells includes a plurality of drivers configured to have an asymmetric drive strength.

12. The method of claim 11, wherein the first plurality of logic cells includes a number of drivers configured to have an equivalent drive strength.

13. The method of claim 11, wherein the first logic cell network and the second logic cell network are within a controller of a memory system.

14. The method of claim 11, wherein the first logic cell network is configured to satisfy a transition time limit associated with the non-static signal path, and wherein the second logic cell network is not configured to satisfy the transition time limit.

15. An apparatus, comprising:
a first logic cell network comprising a first plurality of logic cells associated with a non-static signal path, wherein a first signal corresponding to the non-static signal path is configured for symmetric state transitions during an operating mode of the first logic cell network; and
a second logic cell network comprising a second plurality of logic cells associated with a quasi-static signal path, wherein the second plurality of logic cells includes a plurality of drivers configured to have an asymmetric drive strength, and wherein a second signal corresponding to the quasi-static signal path remains static in a first state during an operating mode of the second logic cell network and has asymmetric characteristics that include a relaxed timing requirement for a transition from the first state to a second state as compared to a transition from the second state to the first state.

16. The apparatus of claim 15, wherein the first signal corresponding to the non-static signal path is a data input/output (I/O) signal, and wherein the second signal corresponding to the quasi-static signal path comprises a Design For Test (DFT) signal, a power management signal, or a reset signal.

17. The apparatus of claim 15, wherein the plurality of drivers configured to have the asymmetric drive strength includes a level shifter, a buffer driver, an inverter, a logic gate, or any combination thereof.

18. The apparatus of claim 15, wherein at least one driver of the plurality of drivers comprises a two-stage buffer driver having a first stage comprising a first pair of transistors and a second stage comprising a second pair of transistors, and wherein at least one of the first pair and the second pair includes a first transistor and a second transistor with the first transistor configured to have a resistance at least twice as high as a resistance of the second transistor.

19. The apparatus of claim 18, wherein one of the first transistor and the second transistor is a PMOS transistor and an other of the first transistor and the second transistor is an NMOS transistor, and wherein which one of the PMOS transistor and the NMOS transistor has the resistance at least twice as high as the resistance of the other of the PMOS transistor and the NMOS transistor is based on to which state a quasi-static signal corresponding to the quasi-static signal path is to be driven during the operating mode of the second logic cell network.

20. The apparatus of claim 18, wherein the first transistor is configured to have a different impedance than that of the second transistor.
